(19) United States
(12) Patent Application Publication
(10) Pub. No.: US 2001/0045616 A1
(43) Pub. Date: Nov. 29, 2001

(54) SEMICONDUCTOR DEVICE HAVING AN INDUCTOR AND METHOD FOR MANUFACTURING THE SAME

(76) Inventor: TAKASHI YOSHITOMI, KAMAKURA-SHI (JP)

Correspondence Address: BANNER & WITCOFF, 1001 G STREET, N.W., WASHINGTON, DC, 200014597

(21) Appl. No.: 09/340,190

(22) Filed: Jun. 28, 1999

(30) Foreign Application Priority Data
Jun. 29, 1998 (JP) 10-198065

(51) Int. Cl. H01L 27/11

(52) U.S. Cl. 257/531

(57) ABSTRACT

An inductor is formed above an element isolation region in a semiconductor substrate, and a grounded shield layer is interposed between the inductor and element isolation region. The shield layer is formed of high-resistance polysilicon, monocrystalline silicon or amorphous silicon doped with low-concentration impurities whose conductivity type is opposite to that of the semiconductor substrate. An impurity diffusion region which is formed in a well under the element isolation region and whose conductivity type is opposite to that of the well, can be used as the shield layer.

### BACKGROUND OF THE INVENTION

The present invention relates to a semiconductor device having an inductor and a method for manufacturing the same.

FIG. 1 is a cross-sectional view of a prior art semiconductor device in which an inductor used in an analog circuit is integrally formed on a silicon chip, FIG. 2 is a plan view of the inductor, and FIG. 3 shows an equivalent circuit of the inductor. Referring to FIGS. 1 to 3, an element isolation region 3 for isolating an element region is formed by LOCOS in a semiconductor substrate 1 such as a P-type silicon semiconductor. An N-well 2 is also formed in the semiconductor substrate 1 so as to extend under the element isolation region 3 from the element region. A first interlayer insulation film 4, which is constituted of, for example, a BPSG (boron-doped phosphosilicate glass) film, is formed on the substrate 1 so as to cover the element region and element isolation region 3. The surface of the insulation film 4 is flattened by CMP (chemical mechanical polishing). A metal film such as an aluminum film is deposited on the flattened surface of the film 4 and patterned in a predetermined shape, thereby forming first metal wirings 5a and 5b.

The first metal wiring 5b is connected to the N-well 2 through a connection plug 6 such as tungsten buried in a contact hole formed in the first interlayer insulation film 4 and thus electrically connected to the semiconductor substrate 1. Then, a second interlayer insulation film 7 of, e.g., SiO₂ is formed on the insulation film 4 by CVD so as to coat the first metal wirings 5a and 5b. The surface of the insulation film 7 is flattened by CMP, and a metal film such as an aluminum film is deposited on the flattened surface of the film 7 and patterned to form a spiral inductor 8. The inductor 8 is electrically connected to the first metal wiring 5a through a connection plug 9 such as tungsten plug buried in a contact hole formed in the second interlayer insulation film 7.

In order to coat the inductor 8, a protecting insulation film such as SiO₂ can be formed on the second interlayer insulation film 7 by a CVD method, or a third interlayer insulation film can be formed on the second interlayer insulation film 7.

The inductor 8, as illustrated in FIG. 2, is connected to a polysilicon resistance element 10 via the first metal wiring 5a. The resistance element 10 is then connected to another element or circuit via the other first metal wiring 5b. Three windings of the inductor 8 are illustrated in FIG. 1.

As is seen from the equivalent circuit of the spiral inductor 8 shown in FIG. 3, a dielectric loss due to the inductor 8 and semiconductor substrate 1 has a great influence on the characteristics of an analog circuit including the inductor 8. The dielectric loss is caused by both a magnetic field generated according to variations in current flowing through the inductor 8 and an eddy current due to the magnetic field. The magnetic field and eddy current degrade the characteristics of the analog circuit. As is apparent from FIG. 3, in order to decrease the dielectric loss or increase value Q of the inductor 8, it is effective to reduce capacitance Csub between the inductor 8 and semiconductor substrate 1 and increase resistance Rsub of the substrate 1 including the N-well 2. When the inductor 8 and resistor 10 are formed on the N-well 2 as shown in FIG. 1, the following problem arises. Even though the impurity concentration of the N-well 2 is as low as 5×10¹⁶ cm⁻², the N-well 2 is as deep as 2 μmm to 3 μmm and the sheet resistance is as low as 2000 Ω/□.

Even though a high-resistance semiconductor substrate whose resistivity is 2000 Ω·cm is used to increase the resistance of the semiconductor substrate, if an element is formed close to a substrate contact, they are coupled to each other in a high-frequency operation and thus the high resistance or high impedance of the substrate is difficult to maintain. The resistance of a substrate is peculiar to the substrate itself, and if the substrate resistance of a well is designed to increase, a semiconductor substrate adapted to the increased resistance is required.

The present invention has been developed in consideration of the above situation, and its object is to provide a semiconductor device having an inductor which is capable of increasing in substrate resistance, avoiding an influence of an element close to a substrate contact even in a high-frequency operation, and preventing an inductance of the inductor and a value Q thereof from decreasing, and a method for manufacturing the semiconductor device.

### BRIEF SUMMARY OF THE INVENTION

The present invention provides a semiconductor device which is so constituted that an inductor is formed on an element isolation region of a semiconductor substrate and a shield layer is interposed between the inductor and element isolation region and opposed to the inductor at a predetermined distance therefrom. With this constitution, the resistance of the substrate can be increased, the influence of an element close to a substrate contact can be avoided, and the inductance and value Q of the inductor can be prevented from decreasing.

A first feature of the semiconductor device of the present invention lies in that a shield layer is opposed to an inductor formed on an element isolation region and constituted of high-resistance polysilicon formed thereon. With the first feature, the resistance of the substrate can be increased, the influence of an element close to a substrate contact can be avoided, and the inductance and value Q of the inductor can be prevented from decreasing.

A second feature of the semiconductor device according to the present invention resides in that a shield layer has a conductivity type opposite to that of a well formed under an element isolation region and is constituted of a shallow, high-concentration, high-sheet resistance impurity diffusion region. With the second feature, the resistance of a substrate can be increased, and the capacitance of the substrate can be reduced because it is coupled in series to a junction capacitance between the shield layer and well. Moreover, the influence of an element close to a substrate contact can be avoided, and the inductance and value Q of an inductor can be prevented from lowering.

The shield layer can be constituted of an impurity diffusion region having a plurality of layers. In this case, the junction capacitance can be coupled in series to the substrate capacitance and thus the effective substrate capacitance can be reduced.

A third feature of the semiconductor device according to the present invention lies in that a shield layer is formed of a low-concentration epitaxial layer or polysilicon layer in an element isolation region. With the third feature, the resistance of a substrate can be increased, the influence of an element close to a substrate contact can be avoided, and the inductance and value Q of the inductor can be prevented from decreasing.

A fourth feature of the semiconductor device according to the present invention resides in that a shield layer is provided with a current blocking structure for blocking an eddy current due to a magnetic field generated by the current flowing through an inductor. With the fourth feature, an image current can be prevented from being generated, a decrease in inductance can be avoided, and a value Q can be improved.

A fifth feature of the semiconductor device according to the present invention lies in that a shield layer includes a trench formed in a direction crossing the direction of current flowing through an inductor in order to block an eddy current due to a magnetic field generated by the current flowing through the inductor. With the fifth feature, an image current can be prevented from being generated, a decrease in inductance can be avoided, and a value Q can be improved.

Furthermore, the shield layer of the present invention is grounded at the same potential as the substrate potential and thus the substrate resistance can be increased. The shield layer and inductor are opposed to each other everywhere to maintain the shield effect.

A first feature of the method for manufacturing a semiconductor device of the present invention lies in that a shield layer of polysilicon is formed in the same step as that of forming a resistance element. The shield layer can thus be formed without increasing the number of manufacturing steps. The resistance element constituted of the same polysilicon as that of the shield layer, may have a sheet resistance which is higher than that of a well.

A second feature of the method for manufacturing a semiconductor device of the present invention lies in that a shield layer is formed in the same step as that of forming a high-impurity diffusion region whose conductivity type is opposite to that of a well formed under an element isolation region. The shield layer can thus be formed without increasing the number of manufacturing steps.

A third feature of the method for manufacturing a semiconductor device of the present invention lies in that a shield layer is formed in the same step as that of forming a high-resistance impurity diffusion region for isolating MOS transistors under an element isolation region. The shield layer can thus be formed without increasing the number of manufacturing steps.

According to the method for manufacturing a semiconductor device of the present invention, a shield layer of a high-resistance impurity diffusion region can be formed in the same step as that of forming an element isolating impurity diffusion region whose conductivity type is opposite to that of a well under an element isolating region. The shield layer can thus be formed without increasing the number of manufacturing steps.

According to the method for manufacturing a semiconductor device of the present invention, a shield layer of a high-resistance impurity diffusion region can be formed in the same step as that of forming a diffusion layer whose conductivity type is opposite to that of the high-resistance impurity diffusion region. The shield layer can thus be formed without increasing the number of manufacturing steps.

According to the method for manufacturing a semiconductor device of the present invention, a shield layer of a high-resistance impurity diffusion region can be formed in the same step as that of forming an element isolating impurity diffusion region whose conductivity type is opposite to that of the high-resistance impurity diffusion region. The shield layer can thus be formed without increasing the number of manufacturing steps.

The polysilicon shield layer used in the semiconductor device of the present invention can be thinned and thus increased in resistance. The shield layer can be increased in resistance by reducing a dose of ion-implantation. If ions of an opposite conductivity type are implanted into the shield layer, its resistance can be lowered.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a cross-sectional view of a prior art semiconductor device having an inductor;

FIG. 2 is a partly perspective plan view of the semiconductor device of FIG. 1 in which an inductor and a resistance element are seen through an interlayer insulation film;

FIG. 3 is an equivalent circuit diagram of the inductor and resistance element shown in FIGS. 1 and 2;

FIG. 4 is a cross-sectional view for explaining a step of manufacturing a semiconductor device according to a first embodiment of the present invention;

FIG. 5 is a cross-sectional view for explaining another step of manufacturing the semiconductor device according to the first embodiment of the present invention;

FIG. 6 is a partly perspective plan view of the semiconductor device of FIG. 5 in which an inductor and a resistance element are partly seen through an interlayer insulation film;

FIG. 7 is a plan view of an example of a shield layer used in a semiconductor device according to a second embodiment of the present invention;

FIG. 8 is a plan view of another example of the shield layer used in the semiconductor device according to the second embodiment of the present invention;

FIG. 9 is a cross-sectional view for explaining a step of manufacturing a semiconductor device according to a third embodiment of the present invention;

FIG. 10 is a cross-sectional view for explaining another step of manufacturing the semiconductor device according to the third embodiment of the present invention; and

FIG. 11 is a cross-sectional view illustrating a semiconductor device according to a fourth embodiment of the present invention.

### DETAILED DESCRIPTION OF THE INVENTION

Embodiments of the present invention will now be described with reference to the accompanying drawings.

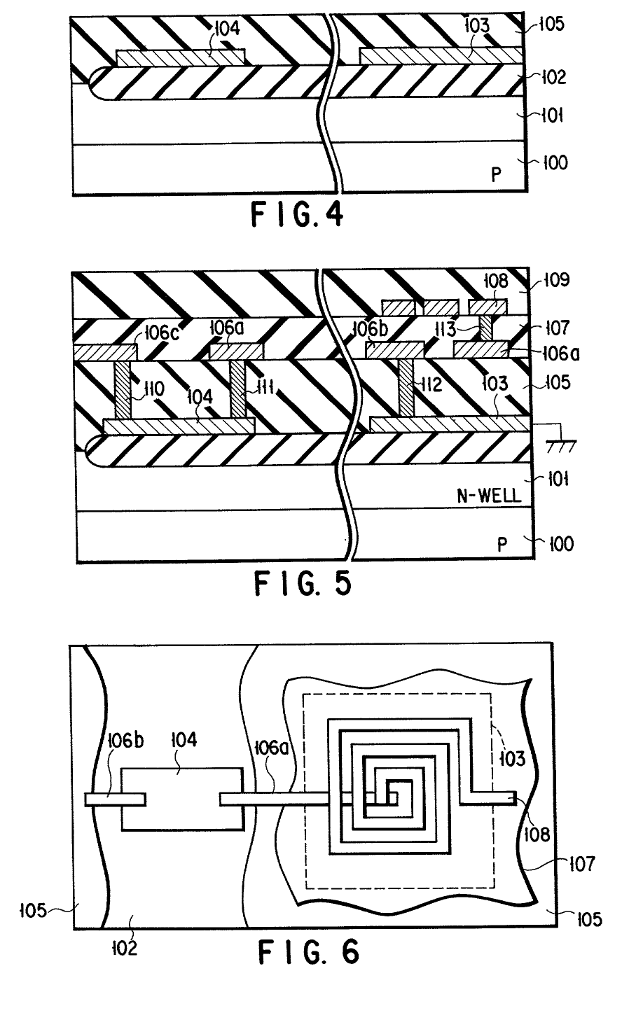

First of all, a first embodiment will be described with reference to FIGS. 4 to 6. FIGS. 4 and 5 are cross-sectional views each illustrating a step of manufacturing a semiconductor device, and FIG. 6 is a partly perspective plan view of the semiconductor device which is partly seen through an interlayer insulation film.

As shown in FIG. 4, an element isolation region 102 for isolating an element region is formed by LOCOS in a semiconductor substrate 100 such as a P-type silicon semiconductor. An N-type well region (N-well) 101 is also formed in the substrate 100 so as to extend under the element isolation region 102 from the element region.

A polysilicon film is formed on the entire major surface of the semiconductor substrate 100 including the N-well 101. BF₂ is ion-implanted into the polysilicon film with energy of 30 KeV and a dose of 7×10¹³ cm⁻² to form a high-resistance polysilicon film.

Though not shown, an epitaxial layer of low impurity concentration may be formed on the element isolation film 102 as a substitution for the polysilicon film.

The high-resistance polysilicon film is patterned by photolithography and RIE (reactive ion etching) to form both a resistance element 104 having a high resistance and a shield layer 103 of an inductor on the element isolation region 102.

A MOSFET (not shown) is formed in the element region and then a silicon oxide film 105 serving as a first interlayer insulation film is formed on the entire major surface of the semiconductor substrate 100 by CVD (chemical vapor deposition) so as to cover the element region and MOSFET. The silicon oxide film 105 is flattened by CMP or the like to obtain the structure shown in FIG. 4.

In the silicon oxide film 105, contact holes are formed on the source, drain and gate of the MOSFET, resistance element 104, and shield layer 103 by photolithography and RIE. Connection plugs are buried into these contact holes and, more specifically, as shown in FIG. 5, connection plugs 110 and 111 are buried into the contact holes formed on the resistance element 104, and a connection plug 112 is buried into the contact hole formed on the shield layer 103.

A pattern of first metal wirings 106a, 106b and 106c of aluminum or the like is formed on the flattened surface of the silicon oxide film 105. The resistance element 104 is connected to the wirings 106a and 106c through their respective connection plugs 111 and 110. The shield layer 103 is connected to the wiring 106b through the connection plug 112. The shield layer 103 is grounded as shown in FIG. 5 through the wiring 106b or through a wiring (not shown).

A silicon oxide film 107 serving as a second interlayer insulation film is formed on the silicon oxide film 105 by CVD so as to cover the first metal wirings 106a, 106b and 106c. The silicon oxide film 107 is flattened by CMP, and a contact hole is formed on the wiring 106a above the shield layer 103 by photolithography and RIE.

A connection plug 113 of tungsten, for example, is buried into the contact hole. A pattern of a second metal wiring of aluminum or the like, or a pattern of an inductor 108 is formed on the flattened surface of the silicon oxide film 107 above the shield layer 103 so that the inductor 108 is connected to the wiring 106a through the connection plug 113.

A silicon oxide film 109 serving as a protecting insulation film is formed on the silicon oxide film 107 by CVD so as to coat the inductor 108 of the second metal wiring. In other words, the second metal wiring 108 is connected to an end portion of the first metal wiring 106a to constitute a part of the inductor 108. The inductor 108 is connected to the resistance element 104 via the wiring 106a formed above the resistance element. The wiring 106a formed above the resistance element 104 and the wiring formed above the shield layer 103 are connected via a connection wiring (not shown). The resistance element 104 is connected to another element or circuit through the first metal wiring 106c. It is part (three windings) of the inductor 108 that is illustrated in FIG. 5.

Referring to the plan view of the semiconductor substrate in FIG. 6, the constitution of the inductor 108 will now be described. The inductor 108 is constituted by both spiral part of the second metal wiring and part of the first metal wirings 106a. The shield layer 103 formed on the element isolation region 102 completely includes the inductor 108. In other words, the shield layer 103 completely overlaps with inductor 108 through the first and second interlayer insulation films 105 and 107. The shield layer 103 is formed of polysilicon in a step of forming the resistance element 104, and connected to the element 104 on the element isolation region 102 through the first metal wiring 106a. The resistance element 104 is connected to another element or circuit through the metal wiring 106c.

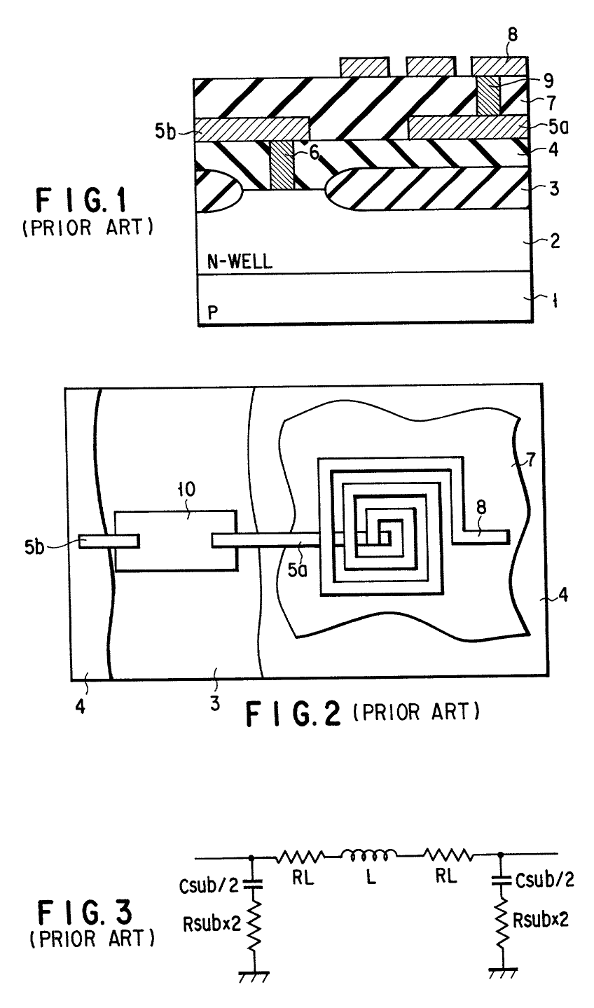

In the prior art method shown in FIG. 2, the substrate resistance (Rsub) is about 2000 Ω/□. In the first embodiment of the present invention, when the high-resistance element 104 of about 2000 Ω/□ is employed, the high-resistance shield layer 103 can be formed simultaneously therewith without increasing the number of manufacturing steps or influencing any other elements, and a decrease in value Q and inductance due to a dielectric loss can be avoided. Moreover, a substrate contact can be prevented from being coupled to its nearby element.

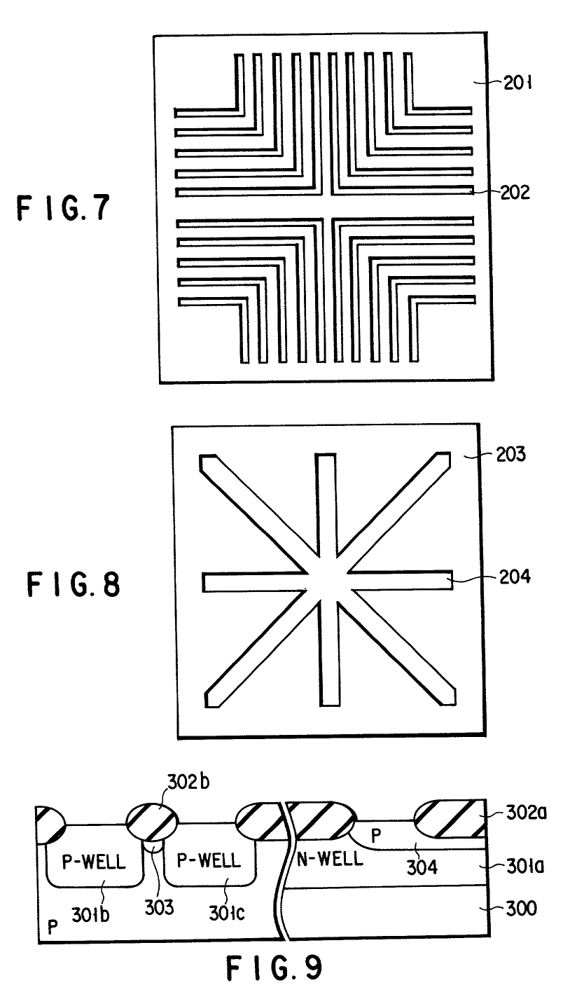

A second embodiment of the present invention will now be described with reference to FIGS. 7 and 8. The shield layer 103 of the first embodiment shown in FIGS. 4 to 6 is formed by only the patterning of polysilicon deposited on the element isolation region 102, whereas the shield layers shown in FIGS. 7 and 8 each include a trench having a predetermined shape.

FIG. 7 illustrates a shield layer 201 as one example. The shield layer 201 includes a plurality of independent trenches 202 formed in a direction crossing currents flowing through the inductor or in a direction crossing eddy currents generated by magnetic lines of force due to the currents flowing through the inductor. The shield layer 201 is so patterned that its surface area is cut by the trenches 202 having a given depth so as to cut the eddy currents.

Accordingly, the use of the shield layer 201 so formed prevents an image current from being generated. The inductor 108 can thus be prevented from decreasing in inductance and improved in value Q.

FIG. 8 illustrates a shield layer 203 as another example. The shield layer 203 has trenches 204 formed radially from the center thereof. The center of the trenches 204 corresponds to that of the inductor formed in the spiral fashion as shown in FIG. 6. Even though the surface area of the shield layer 201 or 203 is cut to a given depth in the trench pattern, they are connected as a single piece and thus every portion thereof has a grounded potential.

In the examples of FIGS. 7 and 8, the trenches 202 and 204 are so patterned that the surfaces of the shield layers 201 and 203 are cut to a given depth by etching in order to block an eddy current caused on the surface areas of the shield layers 201 and 203 due to the magnetic lines of force generated by the current flowing through the inductor 108. Though not shown, the trenches 202 and 204 can be replaced with slits having a similar pattern in order to block the eddy current completely. Even in this case, the shield layers 201 and 203 have the same potential or ground potential because the each layer 201 or 203 is connected as one unit by the peripheral portion thereof, respectively.

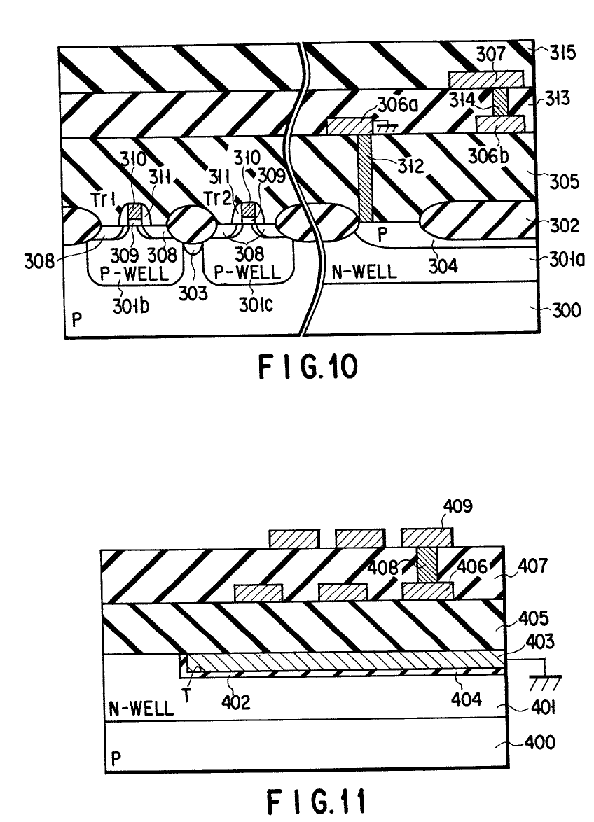

A third embodiment of the present invention will now be described with reference to FIGS. 9 and 10.

FIGS. 9 and 10 are cross-sectional views of a substrate for describing a process of manufacturing a semiconductor device. As shown in FIG. 9, element isolation regions 302a and 302b for isolating an element region are formed by LOCOS in a semiconductor substrate 300 such as a P-type silicon semiconductor. An N-type well region (N-well) 301a in which a shield layer is to be formed, is also formed in the substrate 300 so as to extend under the element isolation region 302a from the element region. In addition to the N-well 301a, P-type well regions (P-wells) 301b and 301c in which an N-type MOS transistor (NMOSFET) is to be formed, are formed in the substrate 300.

In order to separate source and drain regions of the NMOSFET to be formed in the element region by photolithography, boron (B) is ion-implanted into the P-wells 301b and 301c and a region between these P-wells and under the element isolation region 302b at an acceleration voltage of 120 KeV and with a dose of 1×10¹³ cm⁻², thereby forming a P-type impurity diffusion region 303 serving as a punch-through stopper between the P-wells 301b and 301c.

In the third embodiment, the above ion is also implanted into the element isolation region 302a in which an inductor is to be formed and a substrate exposure region (element region) for forming a substrate contact. As a result of the ion-implantation, a P-type impurity diffusion region 304 acting as a shield layer is formed in the N-well 301a of the substrate exposure region and under the element isolation region 302a.

Referring to FIG. 10, impurities are ion-implanted into the P-wells 301b and 301c to form N-type source and drain regions 308. Gate oxide films 309 are formed on a regions between the source and drain regions 308, and gate electrodes 310 are formed on the gate oxide films 309. Insulation side-walls 311 are formed on each side of the gate electrodes 310. Thus, N-type MOS transistors (NMOSFET) Tr1 and Tr2 are formed in the element region.

To cover the MOSFETs Tr1 and Tr2, a silicon oxide film 305 serving as a first interlayer insulation film, is formed by CVD on the entire major surface of the semiconductor substrate 300. The film 305 is then flattened by CMP or the like.

A contact hole is formed in the silicon oxide film 305 to reach the shield layer 304 by photolithography and RIE. A connection plug 312 formed of, e.g., tungsten is buried into the contact hole.

First metal wirings 306a and 306b are formed of, e.g., aluminum and patterned on the flattened surface of the film 305.

The first metal wiring 306a is connected to the shield layer 304 through the connection plug 312.

Another silicon oxide film 313 serving as a second interlayer insulation film, is formed on the silicon oxide film (first interlayer insulation film) 305 by CVD so as to cover the first metal wirings 306a and 306b. The film 313 is then flattened by CMP, and a contact hole is formed in the film 313 to reach the first metal wiring 306b by photolithography and RIE. A connection plug 314 of tungsten is buried into the contact hole.

Then, a second metal wiring 307 is formed of, e.g., aluminum and patterned on the flattened surface of the silicon oxide film 313. The wiring 307 is connected to the first metal wiring 306b through the connection plug 314.

Finally, a silicon oxide film 315 acting as a protecting insulation film is formed on the silicon oxide film 313 by CVD so as to coat the second metal wiring 307.

Though not shown, the second metal wiring 307 connected to an end portion of the first metal wiring 306b, includes a spiral portion, and the spiral portion and the end portion of the wiring 306b constitute an inductor. The inductor body 307 is connected to another element or circuit such as MOS transistors Tr1 and Tr2 through the wiring 306b while the wiring 306a is grounded as shown in FIG. 10. Part of the inductor 307 is shown in FIG. 10.

Since, in the third embodiment, a high-resistance shield layer 304 is used, a decrease in the value Q and inductance of the inductor 307 due to a dielectric loss can be avoided, without increasing the number of manufacturing steps or influencing any other elements.

If a junction capacitance between the shield layer 304 and well 301a is Cd, Csub of the equivalent circuit is expressed as Csub Cd/(Csub+Cd) and the parasitic capacitance is decreased.

Moreover, the substrate contact can be prevented from being coupled to another nearby element in a high-frequency operation. Since a high-resistance shield layer 304 can be formed under the element isolation region 302 without increasing the number of manufacturing steps or influencing any other elements, a junction capacitance between the shield layer 304 and semiconductor substrate or the well 301a can be reduced and consequently the value Q can be improved.

In the third embodiment of FIG. 10, a plurality of diffusion layers can be stacked for the single diffusion layer 304 as shown by the one-dotted lines so as to decrease the effective substrate capacitance because the junction capacitances due to the stacked diffusion layers are connected in series with the substrate capacitance.

A fourth embodiment of the present invention will now be described with reference to FIG. 11.

FIG. 11 is a cross-sectional view of a semiconductor device having an inductor according to the fourth embodiment. An element isolation region 402 for isolating an element region is formed in a semiconductor substrate 400 such as a P-type silicon semiconductor. A shallow trench T is formed in a region of the major surface of the substrate 400 in which the element isolation region 402 is to be formed, and a silicon oxide film 404 is formed on the inner surface of the trench T. The trench T and film 404 constitute the element isolation region as a STI: shallow trench isolation 402.

A shield layer 403 is constituted of polysilicon, amorphous silicon, or monocrystalline silicon and deposited on the silicon oxide film 404 in the trench T.

An N-well 401 is formed in the semiconductor substrate 400 so as to extend under the element isolation region 402 from the element region.

After that, a MOS transistor (not shown) is formed in the element region, and a silicon oxide film 405 serving as a first interlayer insulation film is formed on the entire major surface of the substrate 400 by CVD so as to cover the element region, MOS transistor and shield layer 403. The silicon oxide film 405 is then flattened by CMP.

A first metal wiring 406 is formed of, e.g., aluminum and patterned on the flattened surface of the silicon oxide film 405. A silicon oxide film 407 acting as a second interlayer insulation film is formed on the silicon oxide film 405 by CVD so as to cover the first metal wiring 406. The film 407 is then flattened by CMP, and a contact hole is formed in the film 407 to reach the first metal wiring 406 by photolithography and RIE. A connection plug 408 of tungsten is buried into the contact hole.

Then, a second metal wiring 409, which is constituted of aluminum or the like is deposited to pattern a spiral portion on the flattened surface of the silicon oxide film 407. The second metal wiring 409 is connected to the first metal wiring 406 through the connection plug 408. Finally, thought not shown, a silicon oxide film acting as a protecting insulation film is formed on the silicon oxide film 407 by CVD so as to coat the second metal wiring layer or the inductor 409. An end portion of the first metal wiring 406 and the spiral portion of the second metal wiring 409 constitute the inductor. The inductor body 409 is connected to another element or circuit such as a MOSFET through the first metal wiring 406. Part of the inductor 409 is illustrated in FIG. 11.

In the fourth embodiment of the present invention, when a high-resistance element of about 2000 Ω/□ is employed, a high-resistance shield layer 403, which is formed simultaneously therewith, can be used without increasing the number of manufacturing steps or influencing any other elements. This allows a decrease in the value Q and inductance of the inductor due to a dielectric loss to be avoided. Moreover, a substrate contact can be prevented from being coupled to its nearby element, and a semiconductor substrate in which an element isolation region having an STI structure is formed can be used, thereby improving in miniaturization of the semiconductor device.

With the above-described constitution of the semiconductor device, the substrate resistance can be increased and the capacitance between the shield layer and substrate can be decreased. The influence of an element close to a substrate contact can be avoided, and the inductance and value Q of the inductor can be prevented from decreasing. Furthermore, the high-resistance shield layer can easily be formed without increasing the number of manufacturing steps.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
an inductor formed above an element isolation region formed on the semiconductor substrate; and
a shield layer formed on a surface area of the semiconductor substrate and between the semiconductor substrate and the inductor at a predetermined distance from the inductor.

2. A semiconductor device according to claim 1, wherein the shield layer includes a current blocking structure for blocking a current flowing through the shield layer due to a magnetic field generated by a current flowing through the inductor.

3. A semiconductor device according to claim 1, wherein the shield layer has a trench formed in a direction crossing a direction of a current flowing through the inductor so as to block a current flowing through the shield layer due to a magnetic field generated by the current flowing through the inductor.

4. A semiconductor device according to claim 2, wherein the shield layer has a trench formed in a direction crossing a direction of a current flowing through the inductor so as to block a current flowing through the shield layer due to a magnetic field generated by the current flowing through the inductor.

5. A semiconductor device according to claim 1, wherein the semiconductor substrate includes an element isolation region constituted of a thermal oxide film, and the shield layer is constituted of silicon formed on the thermal oxide film.

6. A semiconductor device according to claim 1, wherein the semiconductor substrate includes a trench and an element isolation region constituted of a silicon oxide film formed on an inner surface of the trench, and the shield layer is constituted of silicon formed on the silicon oxide film.

7. A semiconductor device according to claim 1, wherein the semiconductor substrate includes an element isolation region under which a well is formed, and the shield layer includes at least one impurity diffusion layer which is formed shallowly in a surface area of the well and whose conductivity type is opposite to that of the well.

8. A semiconductor device according to claim 1, wherein a well is formed under the element isolation region of the semiconductor substrate, and the shield layer includes a buried region formed shallowly in a surface area of the well, the buried region containing high-concentration impurities whose conductivity type is opposite to that of the well.

9. A method for manufacturing a semiconductor device comprising the steps of:
forming an element isolation region for isolating an element region in a semiconductor substrate;
forming an inductor above the element isolation region of the semiconductor substrate;
forming a shield layer between the semiconductor substrate and the inductor, the shield layer being opposed to the inductor at a predetermined distance from the inductor; and
forming an element on the semiconductor substrate,
wherein the shield layer is formed simultaneously with a part of the element in the element forming step.

10. A method according to claim 9, further comprising the steps of:
forming a MOS transistor in the element region; and
forming a well under the element isolation region,
wherein the shield layer forming step includes a step of forming at least one impurity diffusion layer of the MOS transistor shallowly in a surface area of the well, the impurity diffusion layer having a conductivity type which is opposite to that of the well, and the shield layer is formed in the step of forming the impurity diffusion layer of the MOS transistor.

11. A method according to claim 9, further comprising the steps of:
forming a thermal oxide film on a semiconductor substrate as the element isolation region; and
forming a well under the element isolation region,
wherein the shield layer forming step includes a step of forming at least one impurity diffusion layer shallowly in a surface area of the well, the impurity diffusion layer having a conductivity type which is opposite to that of the well, wherein the shield layer is formed in the step of forming the impurity diffusion layer of the MOS transistor.

12. A method according to claim 9, wherein the element isolation region forming step includes a step of forming a trench in the semiconductor substrate and a step of forming a silicon oxide film on an inner surface of the trench, the method further comprises a step of forming a well under the element isolation region, the shield layer forming step includes a step of forming an impurity diffusion region of the MOS transistor shallowly in a surface area of the well, the impurity diffusion region having a conductivity type which is opposite to that of the well, and the shield layer is formed in the step of forming the impurity diffusion region of the MOS transistor.

13. A method for manufacturing a semiconductor device comprising the steps of:
forming an element isolation region for isolating an element region in a semiconductor substrate;
forming an inductor on the element isolation region of the semiconductor substrate;
forming a MOS transistor in the element region;
forming a well under the element isolation region; and
forming a shield layer shallowly in a surface area of the well and constituted of an impurity diffusion region whose conductivity type is opposite to that of the well and whose concentration is higher than that of the well,
wherein the shield layer is formed in a step of forming the impurity diffusion region for isolating an element including the MOS transistor.
